(19) United States
(12) Patent Application Publication
(10) Pub. No.: US 2026/0361328 A1
(43) Pub. Date: Nov. 12, 2026

(54) MEMORYLESS DIGITAL PRE-DISTORTION SWITCHING FOR FAST ADAPTIVE POWER TRACKING

(71) Applicant: QUALCOMM Incorporated, San Diego, CA (US)

(72) Inventors: Ilia ANTSIFEROV, Netanya (IL); Natan TAMARI, Haifa (IL); Ariel Yaakov SAGI, Haifa (IL); Lior BEN EZRA, Kiryat Bialik (IL); Guy WOLF, Rosh Haayin (IL)

(21) Appl. No.: 19/201,291

(22) Filed: May 7, 2025

(51) Int. Cl. H04B 1/04; H03F 1/32; H03F 3/24

(52) U.S. Cl. CPC H04B 1/0475; H03F 1/3241; H03F 3/245; H03F 2200/451

(57) ABSTRACT

A system includes a power amplifier and a pre-distortion circuit coupled to the power amplifier, wherein the pre-distortion circuit is configured to perform pre-distortion on an input signal over consecutive time slots based on a pre-distortion profile that compensates for non-linear distortion in the power amplifier. The system also includes an adjustable voltage circuit coupled to the power amplifier, wherein the adjustable voltage circuit is configured to output a supply voltage to the power amplifier and adjust a voltage level of the supply voltage on a per slot basis. The system also includes a switching circuit coupled to the pre-distortion circuit, wherein the switching circuit is configured to adjust the pre-distortion profile on a per slot basis based on the voltage level of the supply voltage.

### BACKGROUND

### Field

Aspects of the present disclosure relate generally to wireless communications, and, more particularly, to pre-distortion for power amplifiers.

### BACKGROUND

In a wireless communication system, a base station transmits radio frequency (RF) signals to and receives RF signals from a user equipment (UE) to provide the UE with wireless coverage. The base station includes a transmitter for transmitting the RF signals to the UE via one or more antennas. The transmitter may include a power amplifier (e.g., Doherty power amplifier) for amplifying the RF signals before transmission. The power amplifier distorts the RF signal due to non-linearities in the power amplifier. To address this, the transmitter may pre-distort the RF signal to compensate for the non-linearities in the power amplifier, resulting in a more linear output at the power amplifier.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system. The system includes a power amplifier and a pre-distortion circuit coupled to the power amplifier, wherein the pre-distortion circuit is configured to perform pre-distortion on an input signal over consecutive time slots to compensate for non-linear distortion in the power amplifier. The system also includes a first register coupled to the pre-distortion circuit, a second register coupled to the pre-distortion circuit, and a memory circuit coupled to the first register and the second register, wherein the memory circuit is configured to store pre-distortion lookup tables (LUTs) corresponding to respective utilization ranges and/or respective supply voltage levels. The system also includes a control circuit coupled to the memory circuit, wherein the control circuit is configured to receive a first indicator indicating a first one of the utilization ranges and/or a first one of the supply volage levels for a first one of the time slots, cause the memory circuit to load a first one of the pre-distortion LUTs corresponding to the first one of the utilization ranges and/or the first one of the supply voltage levels into the first register, receive a second indicator indicating a second one of the utilization ranges and/or a second one of the supply voltage levels for a second one of the time slots, and, during the first one of the time slots, cause the memory circuit to load a second one of the pre-distortion LUTs corresponding to the second one of the utilization ranges and/or the second one of the supply voltage levels into the second register.

A second aspect relates to a method for wireless communication in a system. The system comprising a power amplifier, a pre-distortion circuit coupled to the power amplifier, wherein the pre-distortion circuit is configured to perform pre-distortion on an input signal over consecutive time slots to compensate for non-linear distortion in the power amplifier, and a memory storing pre-distortion lookup tables (LUTs) corresponding to respective utilization ranges and/or respective supply voltage levels. The method includes receiving a first indicator indicating a first one of the utilization ranges and/or a first one of the supply voltage levels for a first one of the time slots, loading a first one of the pre-distortion LUTs corresponding to the first one of the utilization ranges and/or the first one of the supply voltage levels into a first register coupled to the pre-distortion circuit, receiving a second indicator indicating a second one of the utilization ranges and/or a second one of the supply voltage levels for a second one of the time slots, and, during the first one of the time slots, loading a second one of the pre-distortion LUTs corresponding to the second one of the utilization ranges and/or the second one of the supply voltage levels into a second register coupled to the pre-distortion circuit.

A third aspect relates to a system. The system includes a power amplifier and a pre-distortion circuit coupled to the power amplifier, wherein the pre-distortion circuit is configured to perform pre-distortion on an input signal over consecutive time slots based on a pre-distortion profile that compensates for non-linear distortion in the power amplifier. The system also includes an adjustable voltage circuit coupled to the power amplifier, wherein the adjustable voltage circuit is configured to output a supply voltage to the power amplifier and adjust a voltage level of the supply voltage on a per slot basis. The system also includes a switching circuit coupled to the pre-distortion circuit, wherein the switching circuit is configured to adjust the pre-distortion profile on a per slot basis based on the voltage level of the supply voltage.

A fourth aspect relates to a method of wireless communication. The method includes performing pre-distortion on an input signal over consecutive time slots based on a pre-distortion profile that compensates for non-linear distortion in a power amplifier, outputting a supply voltage to the power amplifier, adjusting a voltage level of the supply voltage on a per slot basis, and adjusting the pre-distortion profile on a per slot basis based on the voltage level of the supply voltage.

### BRIEF DESCRIPTION OF THE DRAWINGS

FIG. 1 is a conceptual illustration of a wireless communication system according to certain aspects of the present disclosure.

FIG. 2 shows a block diagram of an example of a system with adaptive power tracking according to certain aspects of the present disclosure.

FIG. 3 shows a plot illustrating an example of power efficiency of a power amplifier versus utilization for different supply voltage levels according to certain aspects of the present disclosure.

FIG. 4 shows an example of a table mapping different utilizations to respective voltage levels for a supply voltage according to certain aspects of the present disclosure.

FIG. 5 shows an example of a digital pre-distortion (DPD) circuit including memory DPD and memoryless DPD according to certain aspects of the present disclosure.

FIG. 6 shows a block diagram of an example of a system with adaptive power tracking and memoryless DPD switching according to certain aspects of the present disclosure.

FIG. 7 shows an example of a table mapping different utilizations to respective voltage levels for the supply voltage and respective pre-distortion lookup tables (LUTs) according to certain aspects of the present disclosure.

FIG. 8 shows an example of voltage level switching and memoryless DPD LUT switching over multiple time slots according to certain aspects of the present disclosure.

FIG. 9 shows an example of a memoryless DPD LUT switching sequence for a first register and a second register according to certain aspects of the present disclosure.

FIG. 10 shows an example in which the system of FIG. 6 also includes memory DPD switching according to certain aspects of the present disclosure.

FIG. 11 is a flowchart illustrating an example of a method for wireless communication according to certain aspects of the present disclosure.

FIG. 12 is a flowchart illustrating another example of a method for wireless communication according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

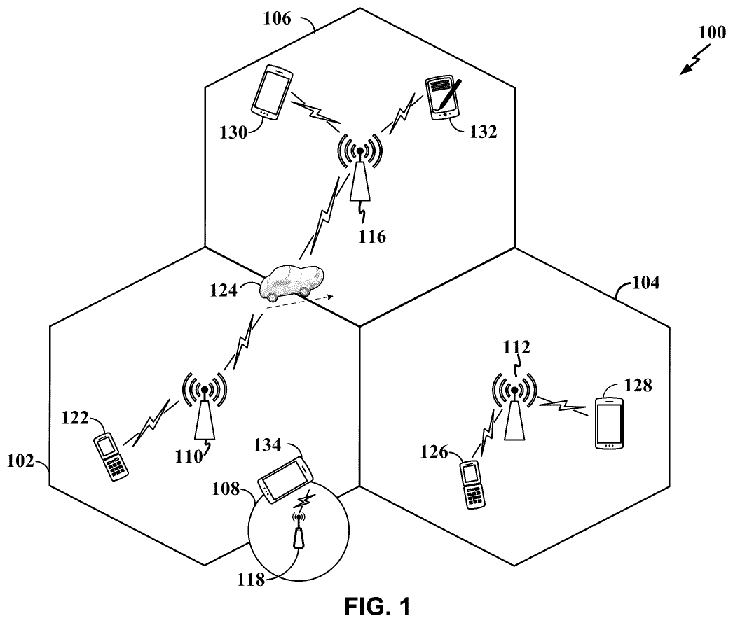

FIG. 1 shows an example of a wireless communication system 100 (e.g., a cellular system) according to certain aspects. The geographic area covered by the wireless communication system 100 may be divided into cellular regions (i.e., cells) that can be uniquely identified by a user equipment (UE) in the wireless communication system 100. FIG. 1 shows an example of macrocells 102, 104, and 106 and a small cell 108, each of which may include one or more sectors (not shown).

Various base station arrangements can be utilized in the wireless communication system 100. In the example shown in FIG. 1, the wireless communication system 100 includes a first base station 110 in the cell 102, a second base station 112 in the cell 104, a third base station 116 in the cell 106, and a fourth base station 118 in the small cell 108 (e.g., a microcell, picocell, femtocell, home base station, home Node B, home eNode B, etc.) which may overlap with the cell 102. The base stations 110, 112, 116, and 118 provide wireless access points to a core network for UEs in the cells 102, 104, 106, and 108. In different technologies, standards, or contexts, a base station may variously be referred to by those skilled in the art as a base transceiver station (BTS), a radio base station, an access point (AP), a Node B (NB), an eNode B (eNB), a gNode B (gNB), or the like. It is to be understood that the wireless communication system 100 may include any number of base stations and cells, and is therefore not limited to the number of base stations and cells shown in the example in FIG. 1.

FIG. 1 shows an example of UEs within the cells 102, 104, 106, and 108. Each of the base stations 110, 112, 116, and 118 may be configured to provide an access point to the core network for the UEs within the respective one of the cells 102, 104, 106, and 108. For example, UEs 122 and 124 may be in communication with the first base station 110, UEs 126 and 128 may be in communication with the second base station 112, UEs 130 and 132 may be in communication with the third base station 116, and UE 134 may be in communication with the fourth base station 118.

In the wireless communication system 100, a UE (e.g., UE 124) may move from a first cell (e.g., a first one of the cells 102, 104, 106, and 108) to a second cell (e.g., a second one of the cells 102, 104, 106, and 108). In this case, the UE may be handed over from the base station in the first cell to the base station in the second cell (i.e., wireless communication with the UE may be transferred from the base station in the first cell to the base station in the second cell). In certain aspects, the UE may monitor the signal quality from its serving cell as well as the signal quality from neighboring cells. During this time, if the UE moves from one cell to another cell, or if the signal quality from a neighboring cell exceeds the signal quality from the serving cell for a given amount of time, then the UE may undertake a handoff or handover from the serving cell to the neighboring cell.

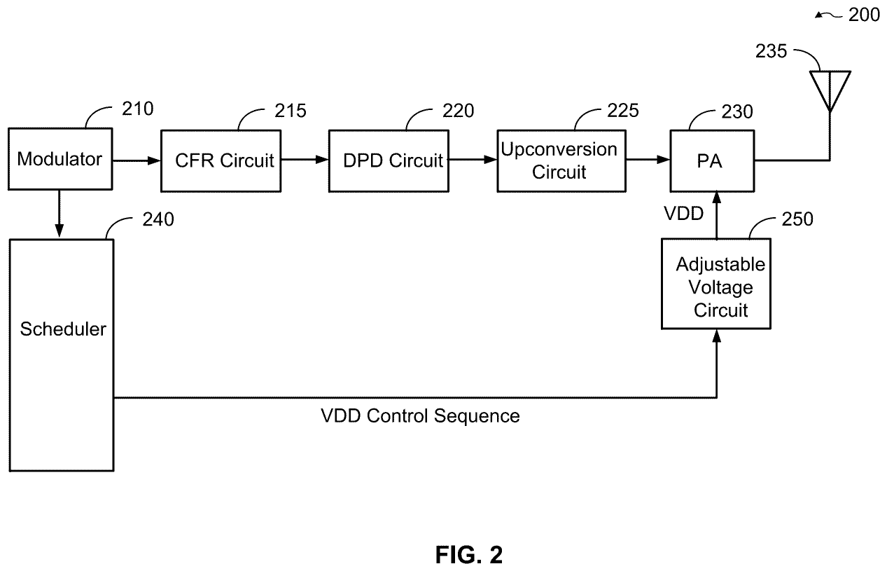

FIG. 2 shows a block diagram of an example of a wireless device 200 according to certain aspects which could be a base station or a UE. The wireless device 200 may correspond to any one of the base stations 110, 112, 116, and 108 shown in FIG. 1 or any one of the UEs 122, 124, 126, 128, 130, 132, and 134 shown in FIG. 1. In this example, the wireless device 200 includes a modulator 210, a crest factor reduction (CFR) circuit 215, a digital pre-distortion (DPD) circuit 220, a frequency upconversion circuit 225, a power amplifier 230, an antenna 235, an adjustable voltage circuit 250, and a scheduler 240.

The modulator 210 is configured to receive data and/or control information and modulate a carrier signal based on the data and/or control information to generate a baseband signal. For example, the modulator 210 may divide the frequency band of the carrier signal into subcarriers and modulate each of the subcarriers using quadrature amplitude modulation (QAM) or another modulation scheme.

The CFR circuit 215 is configured to receive the baseband signal from the modulator 210 and reduce the peak-to-average power ratio (PAPR) of the baseband signal (e.g., to improve power efficiency of the power amplifier 230). The CFR circuit 215 outputs the baseband signal after the PAPR reduction to the DPD circuit 220.

The DPD circuit 220 is configured to pre-distort the baseband signal in the digital domain to compensate for non-linearities in the power amplifier 230 (e.g., by applying an inverse of the non-linear distortion to the baseband signal), resulting in a more linear output at the power amplifier 230. The DPD circuit 220 is discussed in further detail below.

The frequency upconversion circuit 225 receives the baseband signal after pre-distortion by the DPD circuit 220 and frequency upconverts the baseband signal into a radio frequency (RF) signal. For example, the frequency upconversion circuit 225 may frequency upconvert the baseband signal by mixing the baseband signal with a local oscillator (LO) signal.

The power amplifier 230 receives the RF signal from the frequency upconversion circuit 225, amplifies the RF signal, and outputs the amplified RF signal to the antenna 235 for transmission (e.g., to any one of the UEs shown in FIG. 1). The power amplifier 230 may be implemented with a Doherty power amplifier, a load-modulated balanced amplifier, and/or another type of power amplifier. The power amplifier 230 may be fabricated using a gallium nitride (GaN) process or another type of process.

It is to be appreciated that the wireless device 200 may include one or more additional components between the modulator 210 and the antenna 235 not shown in FIG. 2 including, for example, a digital-to-analog converter, a driver, and/or the like.

In certain aspects, the wireless device 200 transmits data to one or more devices (e.g., one or more UEs and/or one or more base stations) in time slots in which the scheduler 240 is configured to schedule the timing of each slot. As discussed further below, the scheduler 240 may communicate the timing of each slot to the adjustable voltage circuit 250 to allow the adjustable voltage circuit 250 to coordinate operations with the slots.

The adjustable voltage circuit 250 is configured to output an adjustable supply voltage VDD to the power amplifier 230 to power the power amplifier 230. The adjustable voltage circuit 250 may include a buck converter and/or another type of DC-to-DC converter capable of generating an adjustable supply voltage with a desired slew rate.

In certain aspects, the wireless device 200 employs fast adaptive power tracking (APT) to improve power efficiency, in which the adjustable voltage circuit 250 adjusts the voltage level of the supply voltage VDD (e.g., on a per slot basis) based on utilization, average transmission power, and/or another parameter. As used herein, “utilization” refers to the proportion of frequencies over which data is transmitted within the overall available bandwidth (e.g., occupied bandwidth (OBW)). A higher utilization uses a larger portion of the overall available bandwidth for transmission than a lower utilization. APT is discussed further below according to certain aspects. As used herein, “per slot basis” refers to one or more parameters that can be adjusted from slot to slot.

In some implementations, the wireless device 200 may transmit data to one or more devices using resource blocks where a resource block is a unit of a time-frequency resource used for transmitting data. Since a resource block uses a portion of the overall available bandwidth (e.g., 12 subcarriers or another number of subcarriers), resource blocks may be used as a measure of utilization. For example, utilization may be determined on a per slot basis in which the utilization for a slot may be determined based on a percentage of the available resource blocks that are allocated for data transmission in the slot. For example, if 80% of the available resource blocks are allocated for data transmission in a slot, then the utilization for the slot may be computed as 80%. It is be appreciated that the present disclosure is not limited to this example and that utilization may be determined using other methods.

As discussed above, APT can improve power efficiency by adjusting (i.e., modulating) the voltage level of the supply voltage VDD (e.g., on a per slot basis) based on utilization, average transmission power, and/or another parameter. The improved power efficiency reduces the energy cost of the wireless device 200.

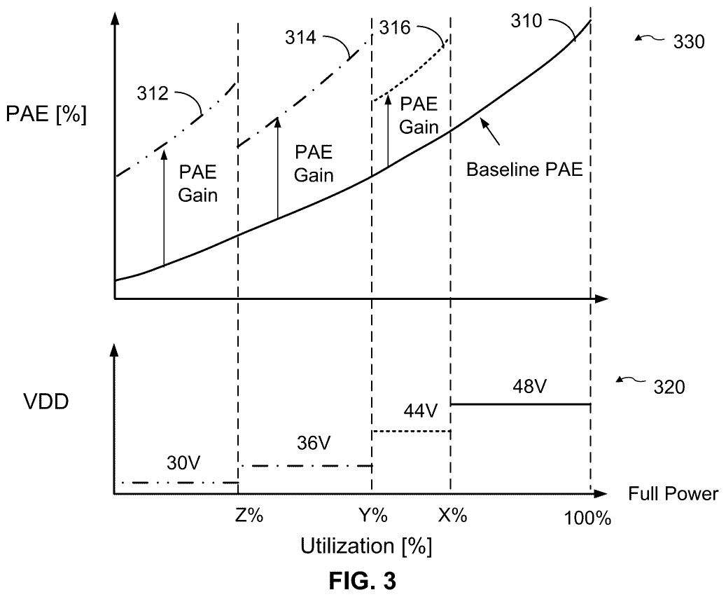

An example of the improved power efficiency is illustrated in FIG. 3. FIG. 3 shows a plot 320 of the voltage level of the supply voltage VDD versus utilization for one example of APT. In this example, the APT may set the voltage level of the supply voltage VDD of the power amplifier 230 to 48V for utilization between X % and 100%, 44V for utilization between Y % and X %, 36V for utilization between Z % and Y %, and 30V for utilization between zero and Z %, where Z % is less than Y %, Y % is less than X %, and X % is less than 100%.

FIG. 3 also shows a plot 330 of power efficiency for the different voltage levels versus utilization. To provide a baseline for comparison, the plot 330 shows the power efficiency 310 for 48V across the entire utilization range (i.e., zero to 100% utilization). As shown in FIG. 3, the power efficiency of the power amplifier 230 drops as the utilization decreases. Thus, maintaining the voltage level of the supply voltage VDD at 48V results in a significant reduction in power efficiency at lower utilizations.

The plot 330 also shows the expected power efficiency 316 for 44V across the utilization range of Y % to X %, the expected power efficiency 314 for 36V across the utilization range of Z % to Y %, and the expected power efficiency 312 for 30V across the utilization range of zero to Z %. As shown in FIG. 3, lowering the voltage level of the supply voltage VDD for the lower utilization ranges results in a significant improvement in the power efficiency of the power amplifier 230 over the baseline (i.e., maintaining the voltage level of at 48V across the entire utilization range).

It is to be appreciated that the present disclosure is not limited to the exemplary voltage levels used in FIG. 3 to illustrate improved power efficiency using APT. Accordingly, it is to be appreciated that other voltage levels may be used in other examples and that the present disclosure is not limited to particular voltage levels.

In certain aspects, the adjustable voltage circuit 250 implements fast APT on a per slot basis. For example, for each slot scheduled by the scheduler 240, the adjustable voltage circuit 250 may receive an indication of the utilization for the slot and set the voltage level of the supply voltage VDD for the slot based on the indicated utilization.

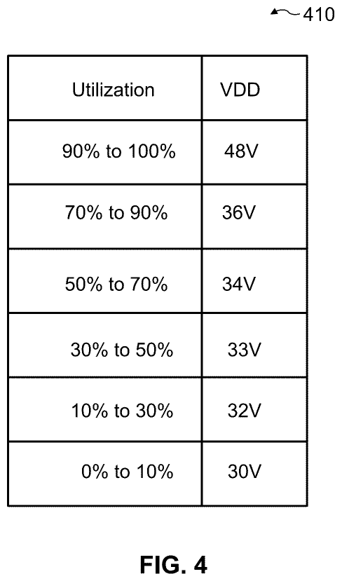

In this regard, FIG. 4 shows an example of a table 410 including different utilization ranges and voltage levels for the supply voltage VDD, in which each of the utilization ranges is mapped to a respective one of the voltage levels for the supply voltage VDD. For example, the utilization range of 90% to 100% may map to a voltage level of 48V, the utilization range of 70% to 90% may map to a voltage level of 36V, the utilization range of 50% to 70% may map to a voltage level of 34V, the utilization range of 30% to 50% may map to a voltage level of 33V, the utilization range of 10% to 30% may map to a voltage level of 32V, and the utilization range of 0% to 10% may map to a voltage level of 30V. However, it is to be appreciated that the exemplary utilization ranges and exemplary voltage levels shown in FIG. 4 are for illustrative purposes and that other utilization ranges and/or other voltage levels may be used in other examples.

In this example, for each slot, the adjustable voltage circuit 250 may receive a utilization signal indicating the utilization range for the slot and set the voltage level of the supply voltage VDD for the slot to the voltage level corresponding to the indicated utilization range. For example, if the indicated utilization range is 70% to 90%, then the adjustable voltage circuit 250 may set the voltage level of the supply voltage VDD to 36V. The adjustable voltage circuit 250 may receive the utilization signal from the scheduler 240 and/or another circuit. As discussed above, the utilization range for a slot may be computed based on the percentage of available resource blocks allocated for the slot and/or another method.

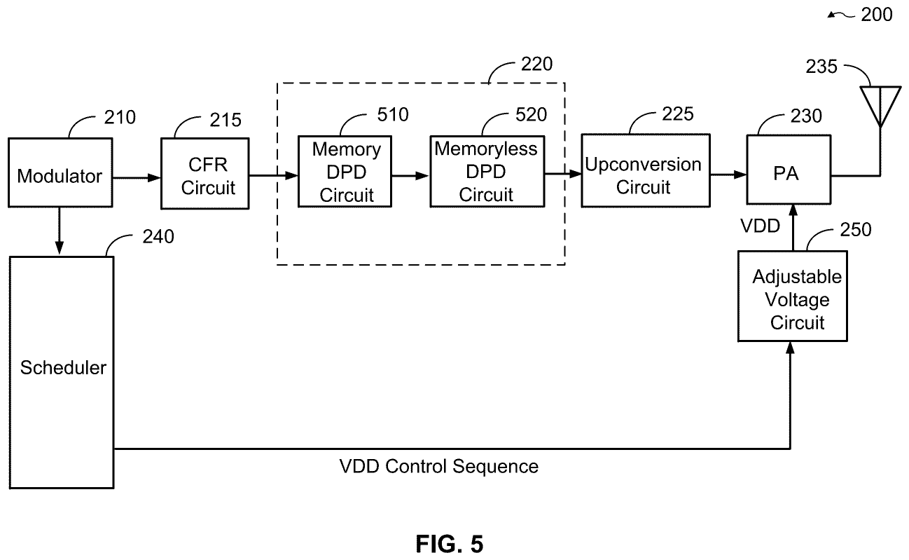

FIG. 5 shows an example in which the DPD circuit 220 includes a memory DPD circuit 510 and a memoryless DPD circuit 520 according to certain aspects. The memory DPD circuit 510 is configured to pre-distort the input signal (e.g., baseband signal) to compensate for the residual non-linearity and memory of the power amplifier 230 that depend on past input powers of the power amplifier 230. The memory DPD circuit 510 may compensate for the power amplifier 230 memory effect using memory polynomials, generalized memory polynomials, dynamic deviation reduction polynomials, and/or other derivatives.

The memoryless DPD circuit 520 is configured to perform pre-distortion on the input signal (e.g., baseband signal) based on a pre-distortion profile that compensates for non-linearities in the power amplifier 230 that depend on the current input power (i.e., current amplitude of the RF signal). For example, the pre-distortion profile may be defined by a lookup table (LUT) that includes different input powers (e.g., input amplitudes) and pre-distortion coefficients, in which each of the input powers (e.g., input amplitudes) is mapped to a respective one of the pre-distortion coefficients. Each of the pre-distortion coefficients in the LUT compensates for non-linear distortion in the power amplifier 230 for the corresponding input power (e.g., input amplitude). In certain aspects, each of the pre-distortion coefficients may be a complex coefficient to compensate for both non-linear gain distortion and non-linear phase distortion in the power amplifier 230. In this example, the memoryless DPD circuit 520 may be configured to detect the current input power (e.g., input amplitude) of the input signal and apply the pre-distortion coefficient corresponding to the detected input power to the input signal.

A challenge with performing both DPD and fast APT is that the fast APT may switch the voltage level of the supply voltage VDD on a per slot basis based on changes in utilization (e.g., due to changes in data traffic) and/or average transmission power from slot to slot. The changes in the voltage level of the supply voltage VDD change the non-linear characteristics of the power amplifier 230 on a per slot basis making it challenging for the memoryless DPD circuit 520 to provide linearization on a per slot basis.

To address this, aspects of the present disclosure provide memoryless DPD LUT switching on a per slot basis. The memoryless DPD LUT switching allows the memoryless DPD circuit 520 to adapt to changes in the supply voltage VDD by the APT on a per slot basis and therefore provide linearization of the power amplifier output on a per slot basis. The above features and other features of the present disclosure are discussed further below.

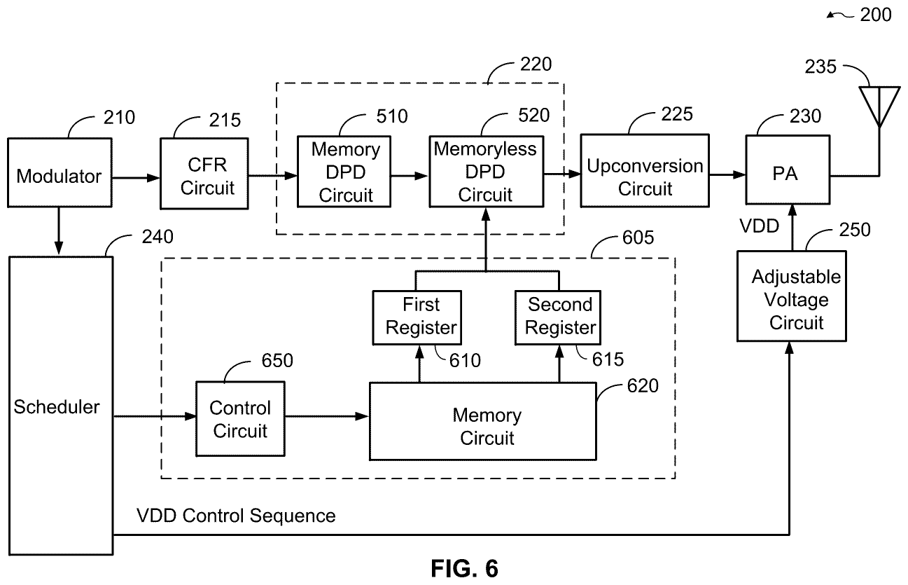

FIG. 6 shows an example in which the wireless device 200 includes a DPD switching circuit 605 to enable memoryless DPD switching on a per slot basis according to certain aspects. In this example, the memoryless DPD circuit 520 performs pre-distortion on the input signal based on the pre-distortion profile, which compensates for memoryless non-linear distortion in the PA 110. In this example, the DPD switching circuit 605 is configured to adjust the pre-distortion profile applied to the input signal by the memoryless DPD circuit 520 on a per slot basis based on the utilization and/or supply voltage level for each slot. For example, the DPD switching circuit 605 may adjust the pre-distortion profile by switching the DPD LUT used by the memoryless DPD circuit 520 to perform pre-distortion on a per slot basis.

In this example, the DPD switching circuit 605 may store sets of pre-distortion coefficients (e.g., in respective LUTs) in which each set of pre-distortion coefficients corresponds to a respective utilization range and/or a respective supply voltage level (e.g., respective one of the utilization ranges and/or respective one of the voltage levels discussed above). For each slot, the switching circuit 605 receives an indicator signal (e.g., from the scheduler 240) indicating the utilization range and/or the supply voltage level for the slot, retrieves the set of pre-distortion coefficients corresponding to the indicated utilization range and/or supply voltage level, and provides the retrieved set of pre-distortion coefficients to the memoryless DPD circuit 520 to perform pre-distortion during the slot. In this way, as the APT changes the supply voltage level on a per slot basis (e.g., to adapt to changes in utilization), the DPD switching circuit 605 adjusts the pre-distortion profile by switching the set of pre-distortion coefficients used by the memoryless DPD circuit 520 to perform pre-distortion on a per slot basis.

In some implementations, the memory DPD circuit 510 shown in the example in FIG. 6 may be optional.

FIG. 6 shows an exemplary implementation of the DPD switching circuit 605 according to certain aspects. In this example, the DPD switching circuit 605 includes a first register 610, a second register 615, a memory circuit 620, and a control circuit 650. The first register 610 and the second register 615 are coupled to the memoryless DPD circuit 520 and the memory circuit 620, and the control circuit 650 is coupled to the scheduler 240 and the memory circuit 620.

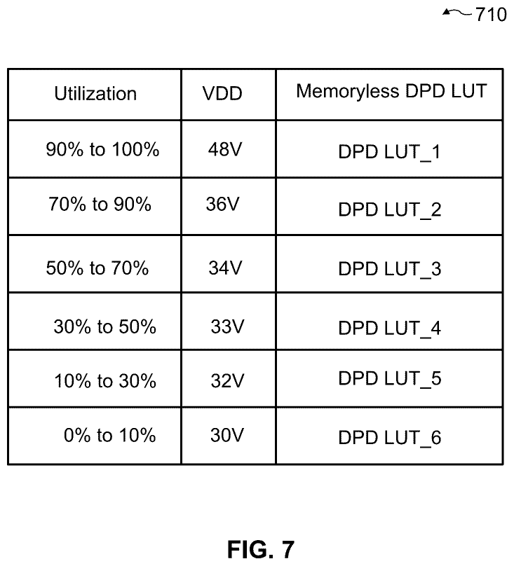

In this example, the memory circuit 620 stores a set of memoryless DPD LUTs where each of the memoryless DPD LUTs corresponds to correction for a different utilization range. In this regard, FIG. 7 shows an example of a table 710 including a set of memoryless DPD LUTs that may be stored in the memory circuit 620. The table 710 also includes examples of the utilization ranges and VDD voltage levels corresponding to the memoryless DPD LUTs in the table 710.

In the example shown in FIG. 7, the set of memoryless DPD LUTs in the table 710 includes six memoryless DPD LUTs labeled DPD LUT_1 to DPD LUT_6, in which DPD LUT_1 corresponds to the utilization range 90% to 100%, DPD LUT_2 corresponds to the utilization range 70% to 90%, DPD LUT_3 corresponds to the utilization range 50% to 70%, DPD LUT_4 corresponds to the utilization range 30% to 50%, DPD LUT_5 corresponds to the utilization range 10% to 30%, and DPD LUT_6 corresponds to the utilization range 0% to 10%. Also, in the example shown in FIG. 7, DPD LUT_1 corresponds to the voltage level 48V, DPD LUT_2 corresponds to the voltage level 36V, DPD LUT_3 corresponds to the voltage level 34V, DPD LUT_4 corresponds to the voltage level 33V, DPD LUT_5 corresponds to the voltage level 32V, and DPD LUT_6 corresponds to the voltage level 30V. It is to be appreciated that present disclosure is not limited to the exemplary utilization ranges and voltage levels shown in FIG. 7 and that other utilization ranges and/or voltage levels may be used in other examples.

In certain aspects, the pre-distortion coefficients in each of the memoryless DPD LUTs in the table 710 may be pretrained to provide non-linear compensation for the respective utilization range. For example, for each memoryless DPD LUT, the amplitude-to-amplitude (AM-AM) response and/or the amplitude-to-phase (AM-PM) response of the power amplifier 230 may be measured for the corresponding utilization range and supply voltage VDD and the pre-distortion coefficients may be pre-trained to compensate for non-linearities in the AM-AM response and/or the AM-PM response. However, it is to be appreciated that the present disclosure is not limited to this example.

Each of the registers 610 and 615 is configured to temporarily store one of the memoryless DPD LUTs in the table 710 from the memory circuit 620 at a time and provide the stored memoryless DPD LUT to the memoryless DPD circuit 520. As discussed further below, the memoryless DPD circuit 520 receives one of the memoryless DPD LUTs from one of the registers 610 or 615 per slot in an alternating fashion to facilitate digital predistortion with per-slot resolution.

In operation, for each slot, the control circuit 650 receives an indicator signal from the scheduler 240 indicating the utilization range (e.g., one of the utilization ranges shown in FIG. 7) and/or the supply voltage level (e.g., one of the supply voltage levels shown in FIG. 7) for the slot. For example, each of the utilization ranges and/or each of the supply voltage levels may be identified by a respective index. In this example, the indicator signal for each slot may indicate the utilization range and/or the supply voltage level for the slot using the respective index. In this example, the control circuit 650 receives the indicator signal for each slot prior to the slot (e.g., during the preceding slot). As discussed above, the utilization range for a slot may be computed based on the percentage of available resource blocks allocated for the slot and/or another method.

For each slot, the control circuit 650 retrieves the memoryless DPD LUT in the memory circuit 620 corresponding to the indicated utilization range and/or the indicated supply voltage level for the slot and loads the retrieved memoryless DPT LUT into one of the registers 610 or 615 prior to the slot (e.g., during the preceding slot). In this example, the control circuit 650 alternates between loading the memoryless DPD LUTs for the slots into the first register 610 and the second register 615. For example, the control circuit 650 may load the memoryless DPD LUTs for the odd slots into the first register 610 during the even slots and load the memoryless DPD LUTs for the even slots into the second register 615 during the odd slots, or vice versa. This allows the control circuit 650 to load the memoryless DPD LUT for the next slot into one of the registers 610 or 615 while the memoryless DPD circuit 520 uses the memoryless DPD LUT for the current slot in the other one of the registers 610 or 615 to perform pre-distortion.

For each slot, the memoryless DPD circuit 520 is configured to use the memoryless DPD LUT in one of the registers 610 or 615 to perform pre-distortion (e.g., using the pre-distortion coefficients in the DPD LUT). The memoryless DPD circuit 520 alternates between using the memoryless DPD LUT in the first register 610 and using the memoryless DPD LUT in the second register 615. For example, the memoryless DPD circuit 520 may use the memoryless DPD LUT in the first register 610 for pre-distortion during the odd slots and use the memoryless DPD LUT in the second register 615 for pre-distortion during the even slots, or vice versa.

In certain aspects, the memoryless DPD circuit 520 is configured to use the memoryless DPD LUT for the current slot in one of the registers 610 or 615 while the DPD LUT for the next slot is being loaded into the other one of the registers 610 or 615. This may be achieved, for example, by having the control circuit 650 load the memoryless DPD LUTs for the odd slots into the first register 610 during the even slots and load the memoryless DPD LUTs for the even slots into the second register 615 during the odd slots, and having the memoryless DPD circuit 520 use the first register 610 to perform pre-distortion during the odd slots and use the second register 615 to perform pre-distortion during the even slots.

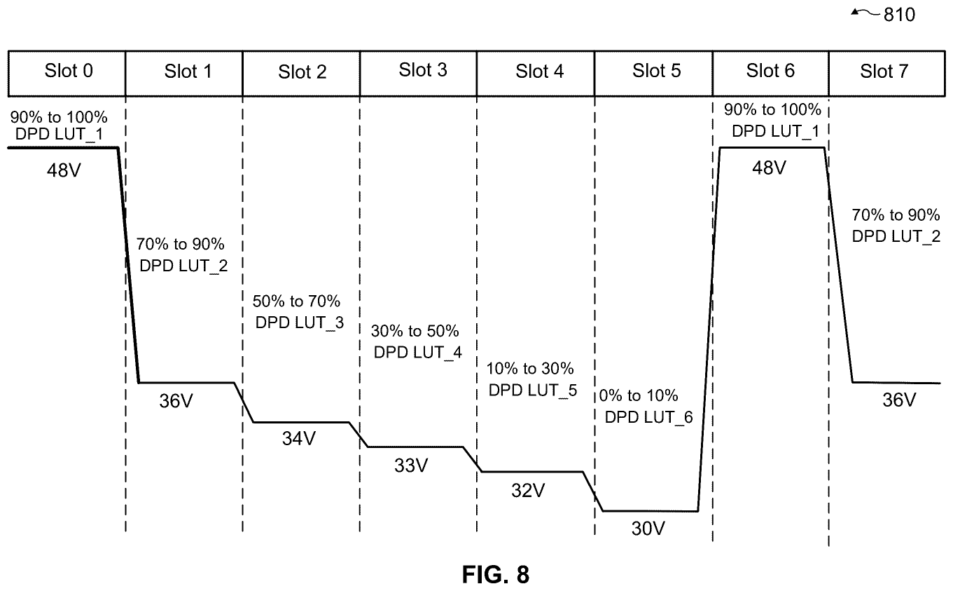

FIG. 8 shows an example of voltage level switching and memoryless DPD LUT switching 810 over multiple time slots (labeled slot 0 to slot 7). During slot 0, the utilization range is 90% to 100%, the adjustable voltage circuit 250 sets the supply voltage VDD to 48V, and the memoryless DPD circuit 520 uses DPD LUT_1 to perform pre-distortion. During slot 1,the utilization range is 70% to 90%, the adjustable voltage circuit 250 sets the supply voltage VDD to 36V, and the memoryless DPD circuit 520 uses DPD LUT_2 to perform pre-distortion. During slot 2, the utilization range is 50% to 70%, the adjustable voltage circuit 250 sets the supply voltage VDD to 34V, and the memoryless DPD circuit 520 uses DPD LUT_3 to perform pre-distortion. During slot 3, the utilization range is 30% to 50%, the adjustable voltage circuit 250 sets the supply voltage VDD to 33V, and the memoryless DPD circuit 520 uses DPD LUT_4 to perform pre-distortion. During slot 4, the utilization range is 10% to 30%, the adjustable voltage circuit 250 sets the supply voltage VDD to 32V, and the memoryless DPD circuit 520 uses DPD LUT_5 to perform pre-distortion. During slot 5, the utilization range is 0% to 10%, the adjustable voltage circuit 250 sets the supply voltage VDD to 30V, and the memoryless DPD circuit 520 uses DPD LUT_6 to perform pre-distortion. During slot 6, the utilization range is 90% to 100%, the adjustable voltage circuit 250 sets the supply voltage VDD to 48V, and the memoryless DPD circuit 520 uses DPD LUT_1 to perform pre-distortion.

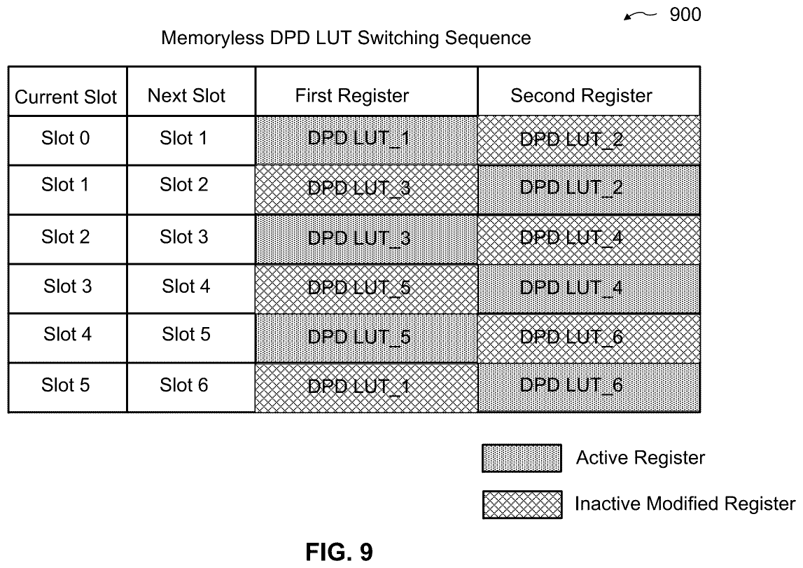

FIG. 9 illustrates a DPD LUT switching sequence 900 for the first register 610 and the second register 615 corresponding to the voltage level switching and DPD LUT switching 810 shown in FIG. 8. In this example, during slot 0, the memoryless DPD circuit 520 uses the DPD LUT_1 in the first register 610 to perform pre-distortion while the control circuit 650 loads the DPD LUT_2 for slot 1 (i.e., the next slot) into the second register 615. During slot 1,the memoryless DPD circuit 520 uses the DPD LUT_2 in the second register 615 to perform pre-distortion while the control circuit 650 loads the DPD LUT_3 for slot 2 (i.e., the next slot) into the first register 610. During slot 2, the memoryless DPD circuit 520 uses the DPD LUT_3 in the first register 610 to perform pre-distortion while the control circuit 650 loads the DPD LUT_4 for slot 3 (i.e., the next slot) into the second register 615. During slot 3, the memoryless DPD circuit 520 uses the DPD LUT_4 in the second register 615 to perform pre-distortion while the control circuit 650 loads the DPD LUT_5 for slot 4 (i.e., the next slot) into the first register 610. During slot 4, the memoryless DPD circuit 520 uses the DPD LUT_5 in the first register 610 to perform pre-distortion while the control circuit 650 loads the DPD LUT_6 for slot 5 (i.e., the next slot) into the second register 615. During slot 5, the memoryless DPD circuit 520 uses the DPD LUT_6 in the second register 615 to perform pre-distortion while the control circuit 650 loads the DPD LUT_1 for slot 6 (i.e., the next slot) into the first register 610.

It is to be appreciated that the exemplary memoryless DPD LUT switching sequence 900 shown in FIG. 9 is intended to illustrate memoryless DPD LUT switching according to aspects of the present disclosure by way of example. Accordingly, it is to be understood that aspects of the present disclosure are not limited to the exemplary memoryless DPD LUT switching sequence 900 shown in FIG. 9.

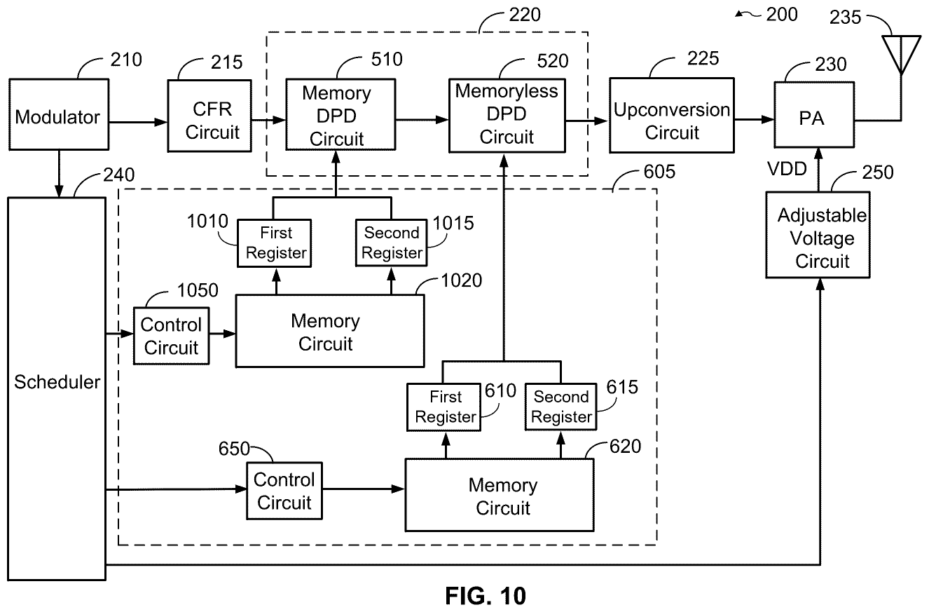

FIG. 10 shows an example in which the wireless device 200 includes memory DPD switching in addition to the memoryless DPD switching according to certain aspects. In this example, the DPD switching circuit 605 is configured to adjust the pre-distortion profile applied to the input signal by the memory DPD circuit 510 on a per slot basis based on the utilization and/or supply voltage level for each slot. For example, the DPD switching circuit 605 may adjust the pre-distortion profile by switching the memory polynomial used by the memory DPD circuit 510 to perform pre-distortion on a per slot basis.

In this example, the DPD switching circuit 605 may store memory polynomials (e.g., in respective LUTs) in which each memory polynomial corresponds to a respective utilization range and/or a respective supply voltage level (e.g., respective one of the utilization ranges and/or respective one of the voltage levels discussed above). Each memory polynomial may be stored as a set of coefficients (e.g., in a respective LUT) modeling the polynomial. For each slot, the switching circuit 605 receives an indicator signal (e.g., from the scheduler 240) indicating the utilization range and/or the supply voltage level for the slot, retrieves the memory polynomial corresponding to the indicated utilization range and/or supply voltage level, and provides the retrieved memory polynomial to the memory DPD circuit 510 to perform pre-distortion during the slot. In this way, as the APT changes the supply voltage level on a per slot basis (e.g., to adapt to changes in utilization), the DPD switching circuit 605 adjusts the pre-distortion profile by switching the memory polynomial used by the memory DPD circuit 510 to perform pre-distortion on a per slot basis.

To perform memory DPD LUT switching, the switching circuit 605 may include a first register 1010, a second register 1015, a memory circuit 1020, and a control circuit 1050. The first register 1010 and the second register 1015 are coupled to the memory DPD circuit 510 and the memory circuit 1020, and the control circuit 1050 is coupled to the scheduler 240 and the memory circuit 1020.

In this example, the memory circuit 1020 stores a set of memory DPD LUTs where each of the memory DPD LUTs corresponds to correction for a different utilization range and/or supply voltage level (e.g., the utilization ranges and/or supply voltage levels in the table 710). For example, each of the memory DPD LUTs may store a respective memory polynomial (e.g., as a set of coefficients modeling the polynomial).

Each of the registers 1010 and 1015 is configured to temporarily store one of the memory DPD LUTs from the memory circuit 1020 at a time and provide the stored memory DPD LUT to the memory DPD circuit 510. As discussed further below, the memory DPD circuit 510 receives one of the memory DPD LUTs from one of the registers 1010 or 1015 per slot in an alternating fashion to facilitate digital predistortion with per-slot resolution.

In operation, for each slot, the control circuit 1050 receives an indicator signal from the scheduler 240 indicating the utilization range and/or the supply voltage level for the slot. For example, each of the utilization ranges and/or each of the supply voltage levels may be identified by a respective index. In this example, the indicator signal for each slot may indicate the utilization range and/or the supply voltage level for the slot using the respective index. In this example, the control circuit 1050 receives the indicator signal for each slot prior to the slot (e.g., during the preceding slot).

For each slot, the control circuit 1050 retrieves the memory DPD LUT in the memory circuit 1020 corresponding to the indicated utilization range and/or the indicated supply voltage level for the slot and loads the retrieved memory DPT LUT into one of the registers 1010 or 1015 prior to the slot (e.g., during the preceding slot). In this example, the control circuit 1050 alternates between loading the memory DPD LUTs for the slots into the first register 1010 and the second register 1015. For example, the control circuit 1050 may load the memory DPD LUTs for the odd slots into the first register 1010 during the even slots and load the memory DPD LUTs for the even slots into the second register 1015 during the odd slots, or vice versa. This allows the control circuit 1050 to load the memory DPD LUT for the next slot into one of the registers 1010 or 1015 while the memory DPD circuit 510 uses the memory DPD LUT for the current slot in the other one of the registers 1010 or 1015 to perform pre-distortion.

For each slot, the memory DPD circuit 510 is configured to use the memory DPD LUT in one of the registers 1010 or 1015 to perform pre-distortion (e.g., using the pre-distortion coefficients in the DPD LUT). The memory DPD circuit 510 alternates between using the memory DPD LUT in the first register 1010 and using the memory DPD LUT in the second register 1015. For example, the memory DPD circuit 510 may use the memory DPD LUT in the first register 1010 for pre-distortion during the odd slots and use the memory DPD LUT in the second register 1015 for pre-distortion during the even slots, or vice versa.

In certain aspects, the memory DPD circuit 510 is configured to use the memory DPD LUT for the current slot in one of the registers 1010 or 1015 while the DPD LUT for the next slot is being loaded into the other one of the registers 1010 or 1015. This may be achieved, for example, by having the control circuit 1050 load the memory DPD LUTs for the odd slots into the first register 1010 during the even slots and load the memory DPD LUTs for the even slots into the second register 1015 during the odd slots, and having the memory DPD circuit 510 use the first register 1010 to perform pre-distortion during the odd slots and use the second register 1015 to perform pre-distortion during the even slots.

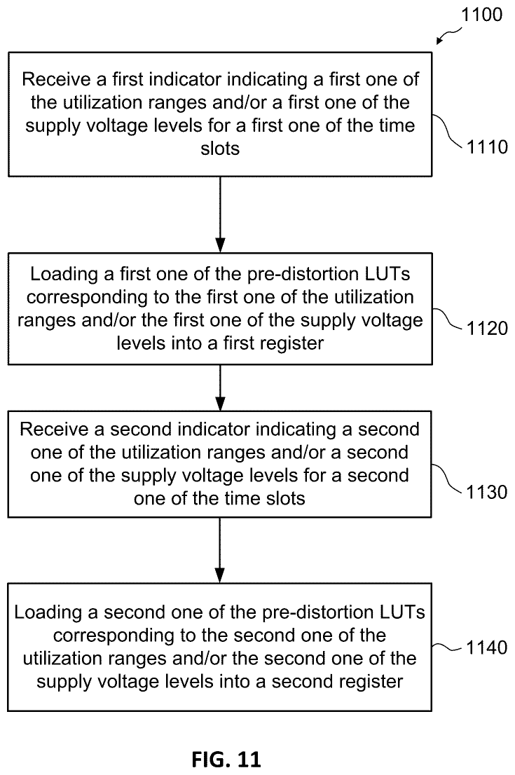

FIG. 11 illustrates a method 1100 for wireless communication. The system includes a power amplifier (e.g., the power amplifier 230), a pre-distortion circuit (e.g., the memoryless DPD circuit 520 and/or the memory DPD circuit 510) coupled to the power amplifier, wherein the pre-distortion circuit is configured to perform pre-distortion on an input signal over consecutive time slots (e.g., slots 0 to slot 7) to compensate for non-linear distortion in the power amplifier, and a memory (e.g., the memory circuit 620 and/or 1020) storing pre-distortion lookup tables (LUTs) (e.g., the memoryless DPD LUTs in table 710) corresponding to respective utilization ranges (e.g., the utilization ranges in table 710) and/or respective supply voltage levels (e.g., the supply voltage levels in table 710).

At block 1110, a first indicator indicating a first one of the utilization ranges and/or a first one of the supply voltage levels for a first one of the time slots is received. The first indicator may be received by the control circuit 650 and/or 1050. The first one of the time slots may correspond to any one of slot 0 to slot 6.

At block 1120, a first one of the pre-distortion LUTs corresponding to the first one of the utilization ranges and/or the first one of the supply voltage levels is loaded into a first register coupled to the pre-distortion circuit. For example, the first one of the pre-distortion LUTs may correspond to any one of DPD LUT_1 to DPD LUT_6. The first register may correspond to the first register 610 and/or 1010. The first one of the pre-distortion LUTs may be loaded into the first register 610 and/or 1010 from the memory circuit 620 and/or 1020 by the control circuit 650 and/or 1050.

At block 1130, a second indicator indicating a second one of the utilization ranges and/or a second one of the supply voltage levels for a second one of the time slots is received. The second indicator may be received by the control circuit 650 and/or 1050. The second one of the time slots may correspond to any one of slot 1 to slot 7.

At block 1140, during the first one of the time slots, a second one of the pre-distortion LUTs corresponding to the second one of the utilization ranges and/or the second one of the supply voltage levels is loaded into a second register coupled to the pre-distortion circuit. For example, the second one of the pre-distortion LUTs may correspond to any one of DPD LUT_1 to DPD LUT_6. The second register may correspond to the second register 615 and/or 1015. The first one of the pre-distortion LUTs may be loaded into the second register 615 and/or 1015 from the memory circuit 620 and/or 1020 by the control circuit 650 and/or 1050.

In certain aspects, the first one of the pre-distortion LUTs corresponding to the first one of the utilization ranges and/or the first one of the supply voltage levels is loaded into the first register before the first one of the time slots (e.g., a time slot immediately preceding the first one of the time slots). In certain aspects, the first one of the time slots immediately precedes the second one of the time slots (i.e., the first one of the time slots and the second one of the time slots are consecutive time slots).

In certain aspects, the method 1100 includes, during the first one of the time slots, performing the pre-distortion on the input signal in the pre-distortion circuit using the first one of the pre-distortion LUTs in the first register, and during the second one of the time slots, performing the pre-distortion on the input signal in the pre-distortion circuit using the second one of the pre-distortion LUTs in the second register.

In certain aspects, each of the pre-distortion LUTs includes respective pre-distortion coefficients corresponding to respective input amplitudes. The pre-distortion coefficients may be complex.

In certain aspects, the method 1100 further includes receiving a third indicator indicating a third one of the utilization ranges and/or a third one of the supply voltage levels for a third one of the time slots, and, during the second one of the time slots, loading a third one of the pre-distortion LUTs corresponding to the third one of the utilization ranges and/or the third one of the supply voltage levels into the first register. For example, the third one of the time slots may correspond to any one of slot 2 to slot 7.

In certain aspects, the first one of the time slots immediately precedes the second one of the time slots, and the second one of the time slots immediately precedes the third one of the time slots (i.e., the first one of the time slots, the second one of the time slots, and the third one of the time slots are consecutive time slots).

In certain aspects, the method 1100 further includes, during the first one of the time slots, performing the pre-distortion on the input signal in the pre-distortion circuit using the first one of the pre-distortion LUTs in the first register, during the second one of the time slots, performing the pre-distortion on the input signal using the second one of the pre-distortion LUTs in the second register, and, during the third one of the time slots, performing the pre-distortion on the input signal using the third one of the pre-distortion LUTs in the first register.

In certain aspects, the method 1100 further includes outputting a supply voltage to the power amplifier, setting the supply voltage to the first one of the supply voltage levels during the first one of the time slots, and setting the supply voltage to the second one of the supply voltage levels during the second one of the time slots. For example, the supply voltage may be output by the adjustable voltage circuit 250, set to the first one of the supply voltage levels by the adjustable voltage circuit 250, and set the second one of the supply voltage levels by the adjustable voltage circuit 250.

In certain aspects, the second one of the utilization ranges is lower than the first one of the utilization ranges, and the second one of the supply voltage levels is lower than the first one of the supply voltage levels.

In certain aspects, the second one of the utilization ranges is higher than the first one of the utilization ranges, and the second one of the supply voltage levels is higher than the first one of the supply voltage levels.

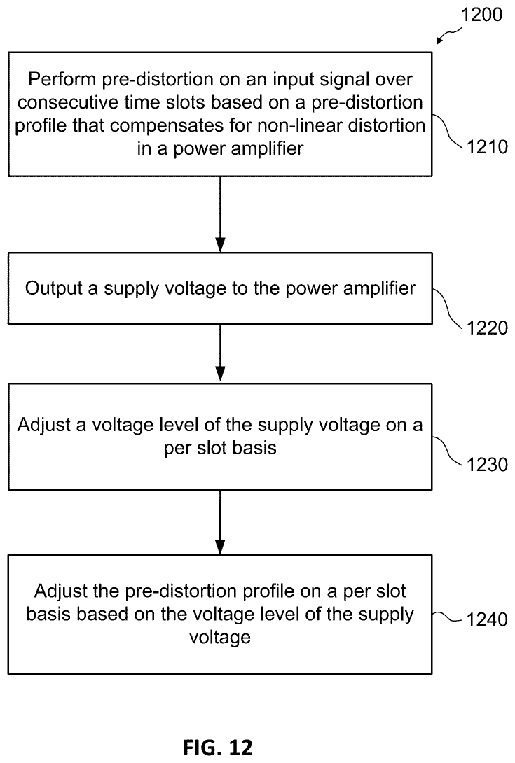

FIG. 12 illustrates another example of a method 1200 for wireless communication.

At block 1210, pre-distortion is performed on an input signal over consecutive time slots based on a pre-distortion profile that compensates for non-linear distortion in a power amplifier. For example, the pre-distortion may be performed by the DPD circuit 220.

At block 1220, a supply voltage is output to the power amplifier. For example, the supply voltage (e.g., VDD) may be output by the adjustable voltage circuit 250.

At block 1230, a voltage level of the supply voltage is adjusted on a per slot basis. For example, the voltage level of the supply voltage may be adjusted by the adjustable voltage circuit 250.

At block 1240, the pre-distortion profile is adjusted on a per slot basis based on the voltage level of the supply voltage. For example, the pre-distortion profile may be adjusted by the DPD switching circuit 605

In certain aspects, adjusting the voltage level of the supply voltage includes, during a first one of the time slots, setting the voltage level of the supply voltage to a first voltage level, and, during a second one of the time slots, setting the voltage level of the supply voltage to a second voltage level. For example, the first one of the time slots and the second one of the time slots may correspond to respective ones of the slots shown in FIGS. 8 and 9.

In certain aspects, adjusting the pre-distortion profile includes, during the first one of the time slots, using a first set of pre-distortion coefficients for the pre-distortion profile, and, during the second one of the time slots, using a second set of pre-distortion coefficients for the pre-distortion profile. For example, the first set of pre-distortion coefficients and the second set of pre-distortion coefficients may be provided in respective ones of the LUTs discussed above.

In certain aspects, adjusting the pre-distortion profile includes, during the first one of the time slots, using a first memory polynomial for the pre-distortion profile, and, during the second one of the time slots, using a second memory polynomial for the pre-distortion profile.

In certain aspects, the method 1200 includes receiving a first indicator indicating a first utilization for the first one of the time slots, wherein setting the voltage level of the supply voltage to the first voltage level comprises setting the voltage level of the supply voltage to the first voltage level based on the first indicator, and receiving a second indicator indicating a second utilization for the second one of the time slots, wherein setting the voltage level of the supply voltage to the second voltage level comprises setting the voltage level of the supply voltage to the second voltage level based on the second indicator.

In certain aspects, the second utilization is lower than the first utilization, and the second voltage level is lower than the first voltage level. In other aspects, the second utilization is higher than the first utilization, and the second voltage level is higher than the first voltage level.

The control circuit 650 and the control circuit 1050 may each be implemented with a general-purpose processor, a digital signal processor (DSP), an application specific integrated circuit (ASIC), a field programmable gate array (FPGA) or other programmable logic device, a digital finite state machine (FSM), discrete hardware components (e.g., logic gates), or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

Implementation examples are described in the following numbered clauses:

1. A system, comprising:
a power amplifier;
a pre-distortion circuit coupled to the power amplifier, wherein the pre-distortion circuit is configured to perform pre-distortion on an input signal over consecutive time slots to compensate for non-linear distortion in the power amplifier;
a first register coupled to the pre-distortion circuit;
a second register coupled to the pre-distortion circuit;
a memory circuit coupled to the first register and the second register, wherein the memory circuit is configured to store pre-distortion lookup tables (LUTs) corresponding to respective utilization ranges and/or respective supply voltage levels; and
a control circuit coupled to the memory circuit, wherein the control circuit is configured to:
   receive a first indicator indicating a first one of the utilization ranges and/or a first one of the supply volage levels for a first one of the time slots;
   cause the memory circuit to load a first one of the pre-distortion LUTs corresponding to the first one of the utilization ranges and/or the first one of the supply voltage levels into the first register;
   receive a second indicator indicating a second one of the utilization ranges and/or a second one of the supply voltage levels for a second one of the time slots; and during the first one of the time slots, cause the memory circuit to load a second one of the pre-distortion LUTs corresponding to the second one of the utilization ranges and/or the second one of the supply voltage levels into the second register.

2. The system of clause 1, wherein the control circuit is configured to cause the memory circuit to load the first one of the pre-distortion LUTs into the first register before the first one of the time slots.

3. The system of clause 1 or 2, wherein the first one of the time slots immediately precedes the second one of the time slots.

4. The system of any one of clauses 1 to 3, wherein the pre-distortion circuit is configured to:
during the first one of the time slots, use the first one of the pre-distortion LUTs in the first register to perform the pre-distortion on the input signal; and
during the second one of the time slots, use the second one of the pre-distortion LUTs in the second register to perform the pre-distortion on the input signal.

5. The system of any one of clauses 1 to 4, wherein each of the pre-distortion LUTs includes respective pre-distortion coefficients corresponding to respective input amplitudes.

6. The system of any one of clauses 1 to 5, wherein the control circuit is configured to:
receive a third indicator indicating a third one of the utilization ranges and/or a third one of the supply voltage levels for a third one of the time slots; and
during the second one of the time slots, cause the memory circuit to load a third one of the pre-distortion LUTs corresponding to the third one of the utilization ranges and/or the third one of the supply voltage levels into the first register.

7. The system of clause 6, wherein the first one of the time slots immediately precedes the second one of the time slots, and the second one of the time slots immediately precedes the third one of the time slots.

8. The system of clause 6 or 7, wherein the pre-distortion circuit is configured to:
during the first one of the time slots, use the first one of the pre-distortion LUTs in the first register to perform the pre-distortion on the input signal;
during the second one of the time slots, use the second one of the pre-distortion LUTs in the second register to perform the pre-distortion on the input signal; and
during the third one of the time slots, use the third one of the pre-distortion LUTs in the first register to perform the pre-distortion on the input signal.

9. The system of any one of clauses 1 to 8, further including an adjustable voltage circuit coupled to the power amplifier, wherein the adjustable voltage circuit is configured to:
output a supply voltage to the power amplifier;
set the supply voltage to the first one of the supply voltage levels during the first one of the time slots; and
set the supply voltage to the second one of the supply voltage levels during the second one of the time slots.

10. The system of clause 9, wherein the second one of the utilization ranges is lower than the first one of the utilization ranges, and the second one of the supply voltage levels is lower than the first one of the supply voltage levels.

11. The system of clause 9, wherein the second one of the utilization ranges is higher than the first one of the utilization ranges, and the second one of the supply voltage levels is higher than the first one of the supply voltage levels.

12. A method for wireless communication in a system, the system comprising a power amplifier, a pre-distortion circuit coupled to the power amplifier, wherein the pre-distortion circuit is configured to perform pre-distortion on an input signal over consecutive time slots to compensate for non-linear distortion in the power amplifier, and a memory storing pre-distortion lookup tables (LUTs) corresponding to respective utilization ranges and/or respective supply voltage levels, wherein the method comprises:
receiving a first indicator indicating a first one of the utilization ranges and/or a first one of the supply voltage levels for a first one of the time slots;
loading a first one of the pre-distortion LUTs corresponding to the first one of the utilization ranges and/or the first one of the supply voltage levels into a first register coupled to the pre-distortion circuit;
   receiving a second indicator indicating a second one of the utilization ranges and/or a second one of the supply voltage levels for a second one of the time slots; and
   during the first one of the time slots, loading a second one of the pre-distortion LUTs corresponding to the second one of the utilization ranges and/or the second one of the supply voltage levels into a second register coupled to the pre-distortion circuit.

13. The method of clause 12, wherein loading the first one of the pre-distortion LUTs into the first register comprises loading the first one of the pre-distortion LUTs into the first register before the first one of the time slots.

14. The method of clause 12 or 13, wherein the first one of the time slots immediately precedes the second one of the time slots.

15. The method of any one of clauses 12 to 14, further comprising:
during the first one of the time slots, performing the pre-distortion on the input signal in the pre-distortion circuit using the first one of the pre-distortion LUTs in the first register; and
during the second one of the time slots, performing the pre-distortion on the input signal in the pre-distortion circuit using the second one of the pre-distortion LUTs in the second register.

16. The method of any one of clauses 12 to 15, wherein each of the pre-distortion LUTs includes respective pre-distortion coefficients corresponding to respective input amplitudes.

17. The method of any one of clauses 12 to 16, further comprising:
receiving a third indicator indicating a third one of the utilization ranges and/or a third one of the supply voltage levels for a third one of the time slots; and
during the second one of the time slots, loading a third one of the pre-distortion LUTs corresponding to the third one of the utilization ranges and/or the third one of the supply voltage levels into the first register.

18. The method of clause 17, wherein the first one of the time slots immediately precedes the second one of the time slots, and the second one of the time slots immediately precedes the third one of the time slots.

19. The method of clause 17 or 18, further comprising:
during the first one of the time slots, performing the pre-distortion on the input signal in the pre-distortion circuit using the first one of the pre-distortion LUTs in the first register;
during the second one of the time slots, performing the pre-distortion on the input signal using the second one of the pre-distortion LUTs in the second register; and vduring the third one of the time slots, performing the pre-distortion on the input signal using the third one of the pre-distortion LUTs in the first register.

20. The method of any one of clauses 12 to 19, further comprising:
outputting a supply voltage to the power amplifier;
setting the supply voltage to the first one of the supply voltage levels during the first one of the time slots; and
setting the supply voltage to the second one of the supply voltage levels during the second one of the time slots.

21. The method of clause 20, wherein the second one of the utilization ranges is lower than the first one of the utilization ranges, and the second one of the supply voltage levels is lower than the first one of the supply voltage levels.

22. The method of clause 20, wherein the second one of the utilization ranges is higher than the first one of the utilization ranges, and the second one of the supply voltage levels is higher than the first one of the supply voltage levels.

23. A system, comprising:
a power amplifier;
a pre-distortion circuit coupled to the power amplifier, wherein the pre-distortion circuit is configured to perform pre-distortion on an input signal over consecutive time slots based on a pre-distortion profile that compensates for non-linear distortion in the power amplifier;
   an adjustable voltage circuit coupled to the power amplifier, wherein the
adjustable voltage circuit is configured to output a supply voltage to the power amplifier and adjust a voltage level of the supply voltage on a per slot basis; and
a switching circuit coupled to the pre-distortion circuit, wherein the switching circuit is configured to adjust the pre-distortion profile on a per slot basis based on the voltage level of the supply voltage.

24. The system of clause 23, wherein the adjustable voltage circuit is configured to:
during a first one of the time slots, set the voltage level of the supply voltage to a first voltage level; and
during a second one of the time slots, set the voltage level of the supply voltage to a second voltage level.

25. The system of clause 24, wherein the switching circuit is configured to:
during the first one of the time slots, provide the pre-distortion circuit with a first set of pre-distortion coefficients for the pre-distortion profile; and
during the second one of the time slots, provide the pre-distortion circuit with a second set of pre-distortion coefficients for the pre-distortion profile.

26. The system of clause 24, wherein the switching circuit is configured to:
during the first one of the time slots, provide the pre-distortion circuit with a first memory polynomial for the pre-distortion profile; and
during the second one of the time slots, provide the pre-distortion circuit with a second memory polynomial for the pre-distortion profile.

27. The system of any one of clauses 24 to 26, wherein the adjustable voltage circuit is configured to:
receive a first indicator indicating a first utilization for the first one of the time slots and set the voltage level of the supply voltage to the first voltage level based on the first indicator; and
receive a second indicator indicating a second utilization for the second one of the time slots and set the voltage level of the supply voltage to the second voltage level based on the second indicator.

28. The system of clause 27, wherein the second utilization is lower than the first utilization, and the second voltage level is lower than the first voltage level.

29. The system of clause 27, wherein the second utilization is higher than the first utilization, and the second voltage level is higher than the first voltage level.

30. A method of wireless communication, comprising:
performing pre-distortion on an input signal over consecutive time slots based on a pre-distortion profile that compensates for non-linear distortion in a power amplifier;
outputting a supply voltage to the power amplifier;
adjusting a voltage level of the supply voltage on a per slot basis; and
adjusting the pre-distortion profile on a per slot basis based on the voltage level of the supply voltage.

31. The method of clause 30, wherein adjusting the voltage level of the supply voltage comprises:
during a first one of the time slots, setting the voltage level of the supply voltage to a first voltage level; and
during a second one of the time slots, setting the voltage level of the supply voltage to a second voltage level.

32. The method of clause 31, wherein adjusting the pre-distortion profile comprises:
during the first one of the time slots, using a first set of pre-distortion coefficients for the pre-distortion profile; and
   during the second one of the time slots, using a second set of pre-distortion coefficients for the pre-distortion profile.

33. The method of clause 31, wherein adjusting the pre-distortion profile comprises:
during the first one of the time slots, using a first memory polynomial for the pre-distortion profile; and
during the second one of the time slots, using a second memory polynomial for the pre-distortion profile.

34. The method of any one of clauses 31 to 33, further comprising:
receiving a first indicator indicating a first utilization for the first one of the time slots, wherein setting the voltage level of the supply voltage to the first voltage level comprises setting the voltage level of the supply voltage to the first voltage level based on the first indicator; and
receiving a second indicator indicating a second utilization for the second one of the time slots, wherein setting the voltage level of the supply voltage to the second voltage level comprises setting the voltage level of the supply voltage to the second voltage level based on the second indicator.

35. The method of clause 34, wherein the second utilization is lower than the first utilization, and the second voltage level is lower than the first voltage level.

36. The method of clause 34, wherein the second utilization is higher than the first utilization, and the second voltage level is higher than the first voltage level.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. The term “approximately” means within a range of between 90 percent and 110 percent of the stated value. A and/or B means A, B, or A and B.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system, comprising:
a power amplifier;
a pre-distortion circuit coupled to the power amplifier, wherein the pre-distortion circuit is configured to perform pre-distortion on an input signal over consecutive time slots to compensate for non-linear distortion in the power amplifier;
a first register coupled to the pre-distortion circuit;
a second register coupled to the pre-distortion circuit;
a memory circuit coupled to the first register and the second register, wherein the memory circuit is configured to store pre-distortion lookup tables (LUTs) corresponding to respective utilization ranges and/or respective supply voltage levels; and
a control circuit coupled to the memory circuit, wherein the control circuit is configured to:
receive a first indicator indicating a first one of the utilization ranges and/or a first one of the supply volage levels for a first one of the time slots;
cause the memory circuit to load a first one of the pre-distortion LUTs corresponding to the first one of the utilization ranges and/or the first one of the supply voltage levels into the first register;
receive a second indicator indicating a second one of the utilization ranges and/or a second one of the supply voltage levels for a second one of the time slots; and
during the first one of the time slots, cause the memory circuit to load a second one of the pre-distortion LUTs corresponding to the second one of the utilization ranges and/or the second one of the supply voltage levels into the second register.

2. The system of claim 1, wherein the control circuit is configured to cause the memory circuit to load the first one of the pre-distortion LUTs into the first register before the first one of the time slots.

3. The system of claim 1, wherein the pre-distortion circuit is configured to:
during the first one of the time slots, use the first one of the pre-distortion LUTs in the first register to perform the pre-distortion on the input signal; and
during the second one of the time slots, use the second one of the pre-distortion LUTs in the second register to perform the pre-distortion on the input signal.

4. The system of claim 1, wherein each of the pre-distortion LUTs includes respective pre-distortion coefficients corresponding to respective input amplitudes.

5. The system of claim 1, wherein the control circuit is configured to:
receive a third indicator indicating a third one of the utilization ranges and/or a third one of the supply voltage levels for a third one of the time slots; and
during the second one of the time slots, cause the memory circuit to load a third one of the pre-distortion LUTs corresponding to the third one of the utilization ranges and/or the third one of the supply voltage levels into the first register.

6. The system of claim 5, wherein the pre-distortion circuit is configured to:
during the first one of the time slots, use the first one of the pre-distortion LUTs in the first register to perform the pre-distortion on the input signal;
during the second one of the time slots, use the second one of the pre-distortion LUTs in the second register to perform the pre-distortion on the input signal; and
during the third one of the time slots, use the third one of the pre-distortion LUTs in the first register to perform the pre-distortion on the input signal.

7. The system of claim 1, further including an adjustable voltage circuit coupled to the power amplifier, wherein the adjustable voltage circuit is configured to:
output a supply voltage to the power amplifier;
set the supply voltage to the first one of the supply voltage levels during the first one of the time slots; and
set the supply voltage to the second one of the supply voltage levels during the second one of the time slots.

8. The system of claim 7, wherein the second one of the utilization ranges is lower than the first one of the utilization ranges, and the second one of the supply voltage levels is lower than the first one of the supply voltage levels.

9. A system, comprising:
a power amplifier;
a pre-distortion circuit coupled to the power amplifier, wherein the pre-distortion circuit is configured to perform pre-distortion on an input signal over consecutive time slots based on a pre-distortion profile that compensates for non-linear distortion in the power amplifier;
an adjustable voltage circuit coupled to the power amplifier, wherein the adjustable voltage circuit is configured to output a supply voltage to the power amplifier and adjust a voltage level of the supply voltage on a per slot basis; and
a switching circuit coupled to the pre-distortion circuit, wherein the switching circuit is configured to adjust the pre-distortion profile on a per slot basis based on the voltage level of the supply voltage.

10. The system of claim 9, wherein the adjustable voltage circuit is configured to:
during a first one of the time slots, set the voltage level of the supply voltage to a first voltage level; and
during a second one of the time slots, set the voltage level of the supply voltage to a second voltage level.

11. The system of claim 10, wherein the switching circuit is configured to:
during the first one of the time slots, provide the pre-distortion circuit with a first set of pre-distortion coefficients for the pre-distortion profile; and
during the second one of the time slots, provide the pre-distortion circuit with a second set of pre-distortion coefficients for the pre-distortion profile.

12. The system of claim 10, wherein the switching circuit is configured to:
during the first one of the time slots, provide the pre-distortion circuit with a first memory polynomial for the pre-distortion profile; and
during the second one of the time slots, provide the pre-distortion circuit with a second memory polynomial for the pre-distortion profile.

13. The system of claim 10, wherein the adjustable voltage circuit is configured to:
receive a first indicator indicating a first utilization for the first one of the time slots and set the voltage level of the supply voltage to the first voltage level based on the first indicator; and
receive a second indicator indicating a second utilization for the second one of the time slots and set the voltage level of the supply voltage to the second voltage level based on the second indicator.

14. The system of claim 13, wherein the second utilization is lower than the first utilization, and the second voltage level is lower than the first voltage level.

15. A method of wireless communication, comprising:
performing pre-distortion on an input signal over consecutive time slots based on a pre-distortion profile that compensates for non-linear distortion in a power amplifier;
outputting a supply voltage to the power amplifier;
adjusting a voltage level of the supply voltage on a per slot basis; and
adjusting the pre-distortion profile on a per slot basis based on the voltage level of the supply voltage.

16. The method of claim 15, wherein adjusting the voltage level of the supply voltage comprises:
during a first one of the time slots, setting the voltage level of the supply voltage to a first voltage level; and
during a second one of the time slots, setting the voltage level of the supply voltage to a second voltage level.

17. The method of claim 16, wherein adjusting the pre-distortion profile comprises:
during the first one of the time slots, using a first set of pre-distortion coefficients for the pre-distortion profile; and
during the second one of the time slots, using a second set of pre-distortion coefficients for the pre-distortion profile.

18. The method of claim 16, wherein adjusting the pre-distortion profile comprises:
during the first one of the time slots, using a first memory polynomial for the pre-distortion profile; and
during the second one of the time slots, using a second memory polynomial for the pre-distortion profile.

19. The method of claim 16, further comprising:
receiving a first indicator indicating a first utilization for the first one of the time slots, wherein setting the voltage level of the supply voltage to the first voltage level comprises setting the voltage level of the supply voltage to the first voltage level based on the first indicator; and
receiving a second indicator indicating a second utilization for the second one of the time slots, wherein setting the voltage level of the supply voltage to the second voltage level comprises setting the voltage level of the supply voltage to the second voltage level based on the second indicator.

20. The method of claim 19, wherein the second utilization is lower than the first utilization, and the second voltage level is lower than the first voltage level.
